(19) United States
(12) Patent Application Publication
(10) Pub. No.: US 2025/0374659 A1
(43) Pub. Date: Dec. 4, 2025

(54) INTEGRATED CIRCUIT DEVICE INCLUDING BIPOLAR JUNCTION TRANSISTOR

(71) Applicant: SAMSUNG ELECTRONICS CO., LTD., Suwon-si (KR)

(72) Inventors: Byungha CHOI, Suwon-si (KR); Seungkwon Kim, Suwon-si (KR); Jaejin Rim, Suwon-si (KR); Dongchan Jeong, Suwon-si (KR); Yuri Masuoka, Suwon-si (KR); Jaehun Jeong, Suwon-si (KR)

(73) Assignee: SAMSUNG ELECTRONICS CO., LTD., Suwon-si (KR)

(21) Appl. No.: 19/223,635

(22) Filed: May 30, 2025

(30) Foreign Application Priority Data
Jun. 3, 2024 (KR) 10-2024-0072649

(51) Int. Cl. H10D 84/40; H10D 10/60; H10D 62/10; H10D 62/60

(52) U.S. Cl. CPC H10D 84/401; H10D 10/60; H10D 62/116; H10D 62/126; H10D 62/60

(57) ABSTRACT

An integrated circuit device may include: a substrate; and a bipolar junction transistor in the substrate, wherein the bipolar junction transistor includes: a first well region of a second conductivity type in the substrate and having a first doping concentration; a second well region adjacent to one side of the first well region in the substrate, of the second conductivity type, and having a second doping concentration that is different from the first doping concentration; a third well region adjacent to another side of the first well region in the substrate and of a first conductivity type; a base on the first well region and having the second conductivity type; an emitter on the second well region and of the first conductivity type; and a collector on the third well region and of the first conductivity type.

### CROSS-REFERENCE TO RELATED APPLICATION

This application is based on and claims priority under 35 U.S.C. § 119 to Korean Patent Application No. 10-2024-0072649, filed on Jun. 3, 2024, in the Korean Intellectual Property Office, the disclosure of which is incorporated by reference herein in its entirety.

### BACKGROUND

### 1. Field

The disclosure relates to an integrated circuit device. More specifically, the disclosure relates to an integrated circuit device including a bipolar junction transistor.

### 2. Description of Related Art

An integrated circuit device may include a metal-oxide semiconductor field effect transistor (MOSFET) and a bipolar junction transistor. The MOSFET has low power consumption and may be highly integrated. Compared to the MOSFET, the bipolar junction transistor has low noise, exhibits a wide range of preceding gain, and has an excellent frequency response characteristic and current driving capability.

However, when the bipolar junction transistor is provided in a substrate together with the MOSFET, a voltage difference dVbe should be uniformly distributed between a base and an emitter of the bipolar junction transistor.

### SUMMARY

One or more embodiments of the disclosure provide an integrated circuit device including a bipolar junction transistor in which a voltage difference dVbe between a base and an emitter, which are arranged in a substrate, is uniformly distributed.

According to one or more aspects of the disclosure, an integrated circuit device may include: a substrate; and a bipolar junction transistor in the substrate, wherein the bipolar junction transistor includes: a first well region of a second conductivity type in the substrate and having a first doping concentration; a second well region adjacent to one side of the first well region in the substrate, of the second conductivity type, and having a second doping concentration that is different from the first doping concentration; a third well region adjacent to another side of the first well region in the substrate and of a first conductivity type; a base on the first well region and having the second conductivity type; an emitter on the second well region and of the first conductivity type; and a collector on the third well region and of the first conductivity type.

The second doping concentration may be greater than the first doping concentration.

The base may have a ring shape around the emitter and the collector has a ring shape around the base.

The integrated circuit device may further include device isolation regions between the base and the emitter and between the base and the collector.

A width of the second well region may be greater than a width of the first well region.

The integrated circuit device may further include a deep well region of the second conductivity type in the substrate. The first well region, the second well region, and the third well region may be on the deep well region.

According to an aspect of the disclosure, an integrated circuit device may include: a P-type substrate; and a bipolar junction transistor in the P-type substrate, wherein the bipolar junction transistor includes: a first N-type well region in the P-type substrate and having a first doping concentration; a second N-type well region adjacent to one side of the first N-type well region in the P-type substrate and having a second doping concentration that is different from the first doping concentration; a third P-type well region adjacent to another side of the first N-type well region in the P-type substrate; an N-type base on the first N-type well region; a P-type emitter on the second N-type well region; and a P-type collector on the third P-type well region.

The second doping concentration may be greater than the first doping concentration, and a width of the second N-type well region may be greater than a width of the first N-type well region.

The integrated circuit device may further include device isolation regions between the N-type base and the P-type emitter and between the N-type base and the P-type collector.

The integrated circuit device may further include: a deep N-type well region in the P-type substrate. The first N-type well region, the second N-type well region, and the third P-type well region may be on the deep N-type well region.

According to an aspect of the disclosure, an integrated circuit device may include: a substrate; a metal-oxide semiconductor field effect transistor in the substrate (MOSFET), the MOSFET including a MOSFET well region of a first conductivity type; and a bipolar junction transistor (BJT) in the substrate, the BJT including: a first well region of a second conductivity type in the substrate and having a first doping concentration; a second well region adjacent to one side of the first well region in the substrate, of the second conductivity type, and having a second doping concentration that is different from the first doping concentration; a third well region adjacent to another side of the first well region in the substrate and of the first conductivity type; a base on the first well region and having the second conductivity type; an emitter on the second well region and of the first conductivity type; and a collector on the third well region and of the first conductivity type.

The second doping concentration may be greater than the first doping concentration.

The base may have a ring shape around the emitter and the collector may have a ring shape around the base.

The integrated circuit device of claim 11, may further include device isolation regions between the base and the emitter and between the base and the collector.

A width of the second well region may be greater than a width of the first well region.

The integrated circuit device may further include a deep well region of the second conductivity type in the substrate. The first well region, the second well region, and the third well region may be on the deep well region.

### BRIEF DESCRIPTION OF THE DRAWINGS

Embodiments will be more clearly understood from the following detailed description taken in conjunction with the accompanying drawings in which:

FIG. 1 is a cross-sectional view of an integrated circuit device including a bipolar junction transistor, according to one or more embodiments;

FIG. 2 is a plan view of a base, an emitter, and a collector of the bipolar junction transistor of FIG. 1 according to one or more embodiments;

FIG. 3 is a cross-sectional view for describing, in detail, a configuration of the bipolar junction transistor of FIG. 1 according to one or more embodiments;

FIG. 4 is a cross-sectional view for describing an integrated circuit device including a bipolar junction transistor and a metal-oxide semiconductor field effect transistor (MOSFET), according to one or more embodiments;

FIG. 5 is a cross-sectional view for schematically describing an integrated circuit device including a bipolar junction transistor, according to one or more embodiments;

FIG. 6 is a cross-sectional view of an integrated circuit device including a bipolar junction transistor of a comparative example, to be compared with an integrated circuit device of the disclosure according to one or more embodiments;

FIG. 7 is a diagram showing a distribution of a voltage difference between a base and an emitter of a bipolar junction transistor of an integrated circuit device, according to one or more embodiments;

FIG. 8 is a diagram showing a distribution of a voltage difference between a base and an emitter of a bipolar junction transistor of an integrated circuit device, according to one or more embodiments; and

FIG. 9 is a diagram showing a distribution of a voltage difference between a base and an emitter of a bipolar junction transistor of an integrated circuit device, according to one or more embodiments.

### DETAILED DESCRIPTION

Hereinafter, embodiments will be described in detail with reference to accompanying drawings. In the drawings, like reference numerals are used for like elements and redundant descriptions thereof will be omitted.

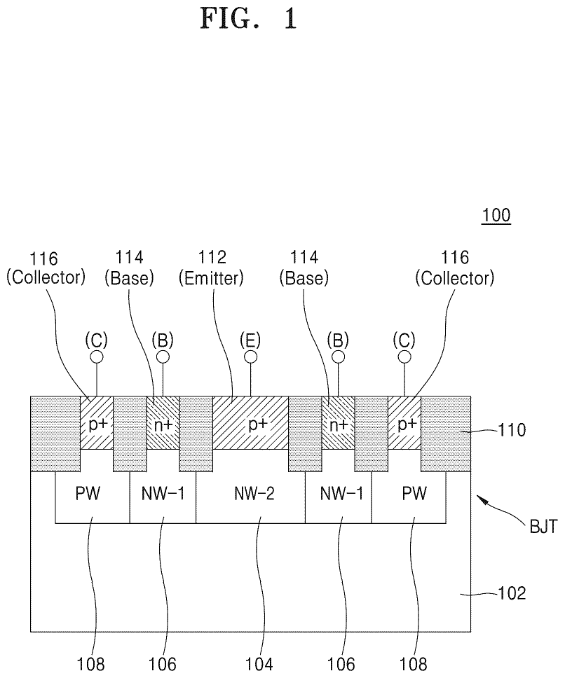

FIG. 1 is a cross-sectional view of an integrated circuit device 100 including a bipolar junction transistor (BJT), according to one or more embodiments.

In detail, the integrated circuit device 100 may include a substrate 102 and the bipolar junction transistor BJT in the substrate 102. The integrated circuit device 100 may include a metal-oxide semiconductor field effect transistor (MOSFET).

The integrated circuit device 100 includes a plurality of bipolar junction transistors BJT in the substrate 102, but in FIG. 1, only two bipolar junction transistors BJT are illustrated for convenience.

For convenience of description, a configuration of the bipolar junction transistor BJT will be described by using one bipolar junction transistor BJT. In addition, in the description below, a PNP bipolar junction transistor is described, but the disclosure may also be applied to an NPN bipolar junction transistor.

The bipolar junction transistor BJT may be a vertical bipolar junction transistor. The vertical bipolar junction transistor BJT may be a passive device that exhibits a junction temperature characteristic well. The vertical bipolar junction transistor BJT may be a representative device used for a temperature monitoring unit (TMU).

The substrate 102 may have a first conductivity type. For example, the substrate 102 may be a P-type substrate. The substrate 102 may be a P-type silicon substrate. The substrate 102 may have a doping concentration of P-type impurities, e.g., boron (B), of about 10¹⁴/cm³. In one or more embodiments, components of the bipolar junction transistor BJT are provided in the substrate 102, but the components of the bipolar junction transistor BJT may be provided in a P-type epitaxial layer after forming the P-type epitaxial layer on the substrate 102 through an epitaxial process.

The bipolar junction transistor BJT may include a first well region 106 arranged in the substrate 102 and having a second conductivity type. The first well region 106 may be a first N-type well region NW-1. The first well region 106 may have a first doping concentration.

The first well region 106 may be formed by injecting, into the substrate 102, ions of second conductivity type impurities (N-type impurities), e.g., arsenic (As) or phosphorus (P). The first well region 106 may have the first doping concentration of the N-type impurities, e.g., As or P, of about 10¹⁷/cm³.

The bipolar junction transistor BJT may include a second well region 104 arranged adjacent to one side of the first well region 106 in the substrate 102 and having the second conductivity type. The second well region 104 may be a second N-type well region NW-2.

The second well region 104 may be formed by injecting, into the substrate 102, ions of second conductivity type impurities (N-type impurities), e.g., As or P. The second well region 104 may have the second doping concentration of the N-type impurities, e.g., As or P, of about 10¹⁸/cm³.

The second well region 104 may have the second doping concentration that is different from the first doping concentration of the first well region 106. According to some embodiments, the second doping concentration of the second well region 104 may be greater than the first doping concentration of the first well region 106. According to some embodiments, in a plan view, the first well region 106 may have a ring shape surrounding (around) the second well region 104.

The bipolar junction transistor BJT may include a third well region 108 arranged adjacent to the other side of the first well region 106 in the substrate 102 and having the first conductivity type. The third well region 108 may be a third P-type well region PW. The third well region 108 may have a ring shape surrounding (around) the first well region 106, in a plan view.

The third well region 108 may be formed by injecting, into the substrate 102, ions of first conductivity type impurities (P-type impurities), e.g., boron (B). The third well region 108 may have a doping concentration of the P-type impurities, e.g., B, of about 10¹⁷/cm³.

The bipolar junction transistor BJT includes a base 114 arranged on the first well region 106 and having the second conductivity type. The base 114 may be a high concentration N-type impurity region (n+ region). The first well region 106 covers an entire lower surface of the base 114. A base electrode B may be connected to the base 114.

The bipolar junction transistor BJT includes an emitter 112 arranged on the second well region 104 and having the first conductivity type. The emitter 112 may be a high concentration P-type impurity region (p+ region). The second well region 104 covers an entire lower surface of the emitter 112. An emitter electrode E may be connected to the emitter 112.

The bipolar junction transistor BJT includes a collector 116 arranged on the third well region 108 and having the first conductivity type. The collector 116 may be a high concentration P-type impurity region (p+ region). The third well region 108 covers an entire lower surface of the collector 116. A collector electrode C may be connected to the collector 116.

The bipolar junction transistor BJT includes device isolation regions 110 between the base 114 and the emitter 112 and between the base 114 and the collector 116. The device isolation regions 110 may include an insulating layer, e.g., an oxide layer.

The first well region 106 may be arranged below the base 114 and below the device isolation regions 110. The second well region 104 may be arranged below the emitter 112 and below the device isolation regions 110. The third well region 108 may be arranged below the collector 116 and below the device isolation regions 110.

The bipolar junction transistor BJT of the integrated circuit device 100 may divide a well region below the base 114 and the emitter 112 into the first well region 106 and the second well region 104. In addition, the first doping concentration of the first well region 106 and the second doping concentration of the second well region 104 are different from each other. According to some embodiments, the second doping concentration of the second well region 104 is greater than the first doping concentration of the first well region 106.

Here, a voltage difference between the base 114 and the emitter 112 when a current is applied between the base 114 and the emitter 112 may be indicated by Vbe. A voltage differences according to currents applied to the plurality of bases 114 and the emitter 112 on the substrate 102 may be indicated by delta Vbe (dVbe).

When configured as above, a junction location of the first well region 106 and the second well region 104 may be moved to a lower portion of the substrate 102 by adjusting the first doping concentration of the first well region 106 and the second doping concentration of the second well region 104 between the base 114 and the emitter 112. Accordingly, the bipolar junction transistor BJT may have an improved characteristic of a transistor, e.g., an improved uniform distribution of the voltage difference dVbe between the base 114 and the emitter 112.

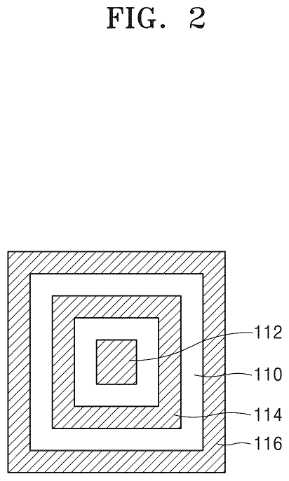

FIG. 2 is a plan view of the base 114, the emitter 112, and the collector 116 of the bipolar junction transistor BJT of FIG. 1.

In detail, in FIG. 2, like reference numerals as in FIG. 1 denote like elements. Details that have been described with reference to FIG. 1 will be briefly described or omitted in FIG. 2. As described above, in a plan view, the first well region 106 may have a ring shape surrounding (around) the second well region 104. The third well region 108 may have a ring shape surrounding (around) the first well region 106, in a plan view.

Accordingly, the base 114 may have a ring shape surrounding (around) the emitter 112. The collector 116 may have a ring shape surrounding (around) the base 114. Also, the device isolation regions 110 may each be arranged between the emitter 112, the base 114, and the collector 116.

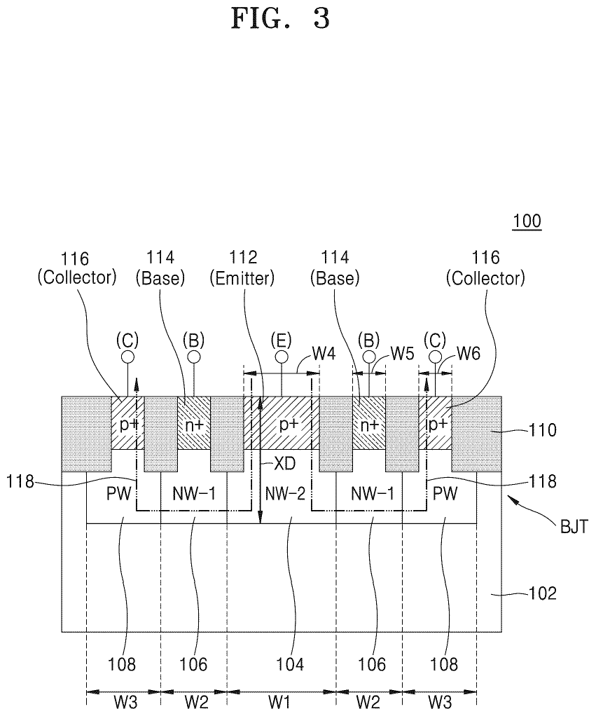

FIG. 3 is a cross-sectional view for describing, in detail, a configuration of the bipolar junction transistor BJT of FIG. 1.

In detail, in FIG. 3, like reference numerals as in FIG. 1 denote like elements. Details that have been described with reference to FIG. 1 will be briefly described or omitted in FIG. 3. The bipolar junction transistor BJT includes the first well region 106, the second well region 104, and the third well region 108, which are arranged in the substrate 102.

The first well region 106, the second well region 104, and the third well region 108 have a depth XD from a surface of the substrate 102. The depth XD may be a junction depth. According to some embodiments, the depth XD may be 1 micrometer or less.

The first well region 106 may have a width W2. The second well region 104 may have a width W1. The third well region 108 may have a width W3. According to some embodiments, the width W2 of the first well region 106 may be less than the width W1 of the second well region 104. According to some embodiments, the width W3 of the third well region 108 may be almost the same as the width W2 of the first well region 106. The widths W1, W2, and W3 may be 1 micrometer or less.

As described above, the second doping concentration of the second well region 104 may be different from the first doping concentration of the first well region 106. According to some embodiments, the second doping concentration of the second well region 104 may be greater than the first doping concentration of the first well region 106.

The bipolar junction transistor BJT includes the base 114, the emitter 112, and the collector 116, which are arranged in the substrate 102. The base 114 may have a width W5. The emitter 112 may have a width W4. The collector 116 may have a width W6. According to some embodiments, the width W5 of the base 114 may be less than the width W4 of the emitter 112. According to some embodiments, the width W5 of the base 114 may be almost the same as the width W6 of the collector 116.

In the bipolar junction transistor BJT, a current may flow from the emitter 112 to the collector 116 through the base 114, as indicated by a reference numeral 118. In the bipolar junction transistor BJT, as indicated by the reference numeral 118, the current may flow from the emitter 112 to the collector 116 through the base 114, by passing through the second well region 104, the first well region 106, and the third well region 108.

As described above, in the bipolar junction transistor BJT, the current may flow between the base 114 and the emitter 112 by adjusting the first doping concentration of the first well region 106 and the second doping concentration of the second well region 104 to change the junction location of the first well region 106 and the second well region 104 to the lower portion of the substrate 102.

Accordingly, the bipolar junction transistor BJT may have an improved characteristic of a transistor, e.g., an improved uniform distribution of the voltage difference dVbe between the base 114 and the emitter 112.

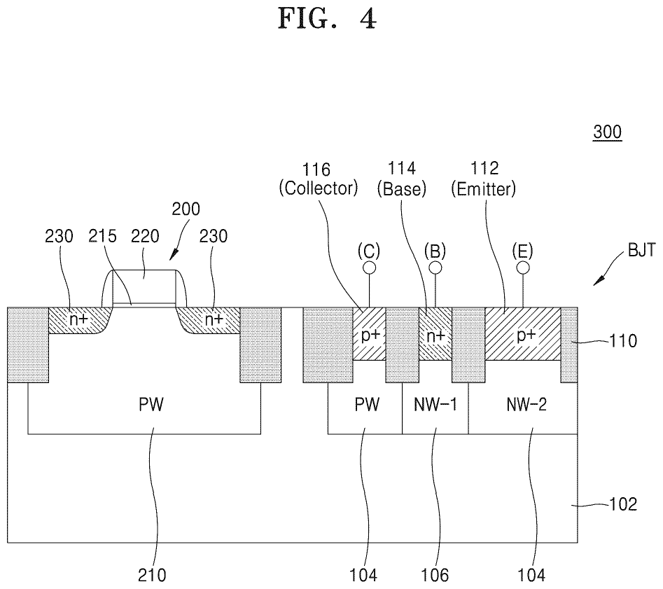

FIG. 4 is a cross-sectional view for describing an integrated circuit device 300 including the bipolar junction transistor BJT and a MOSFET 200, according to one or more embodiments.

In detail, in FIG. 4, like reference numerals as in FIGS. 1 to 3 denote like elements. Details that have been described with reference to FIGS. 1 to 3 will be briefly described or omitted in FIG. 4. The integrated circuit device 300 may include the MOSFET 200 and the bipolar junction transistor BJT. The bipolar junction transistor BJT has been described above, and thus, descriptions thereof are not provided again.

The integrated circuit device 300 includes the MOSFET 200 arranged adjacent to the bipolar junction transistor BJT. The MOSFET 200 may include a well region 210 having the first conductivity type, a gate insulating layer 215 and gate electrode 220 on the well region 210, and source/drain regions 230 provided on opposite sides of the gate electrode 220 and having the second conductivity type. The well region 210 may be a P-type well region PW. The source/drain regions 230 may be n+ regions.

In FIG. 4, the MOSFET 200 is illustrated as an N-type MOSFET for convenience, but a P-type MOSFET may be arranged in the substrate 102. In FIG. 4, the MOSFET 200 is illustrated as a planar type MOSFET for convenience, but a fin type MOSFET or a 3-dimensional MOSFET may be arranged in the substrate 102.

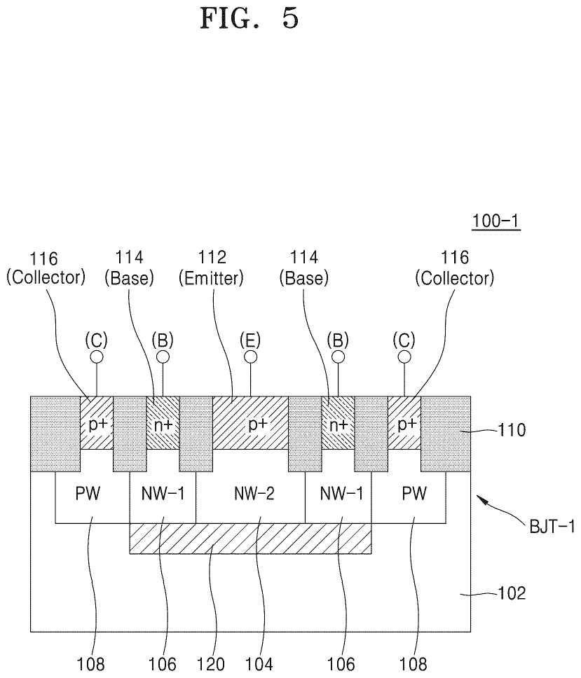

FIG. 5 is a cross-sectional view for schematically describing an integrated circuit device 100-1 including a bipolar junction transistor BJT-1, according to one or more embodiments.

In detail, the integrated circuit device 100-1 may be the same as the integrated circuit device 100 of FIGS. 1 to 3, except that the integrated circuit device 100-1 includes the bipolar junction transistor BJT-1 further including a deep well region 120. In FIG. 5, like reference numerals as in FIGS. 1 to 3 denote like elements. Details that have been described with reference to FIGS. 1 to 3 will be briefly described or omitted in FIG. 5.

The integrated circuit device 100-1 may include the bipolar junction transistor BJT-1 in the substrate 102, the bipolar junction transistor BJT-1 further including the deep well region 120 having the second conductivity type. The deep well region 120 may be arranged below the first well region 106, the second well region 104, and the third well region 108. The first well region 106, the second well region 104, and the third well region 108 may be arranged on the deep well region 120. The deep well region 120 may be a deep N-type well region.

The bipolar junction transistor BJT-1 may allow a current to flow through the first well region 106, the second well region 104, and the deep well region 120, which have satisfactory interface characteristics between the base 114 and the emitter 112. Accordingly, the bipolar junction transistor BJT-1 may have an improved characteristic of a transistor, e.g., an improved uniform distribution of the voltage difference dVbe between the base 114 and the emitter 112.

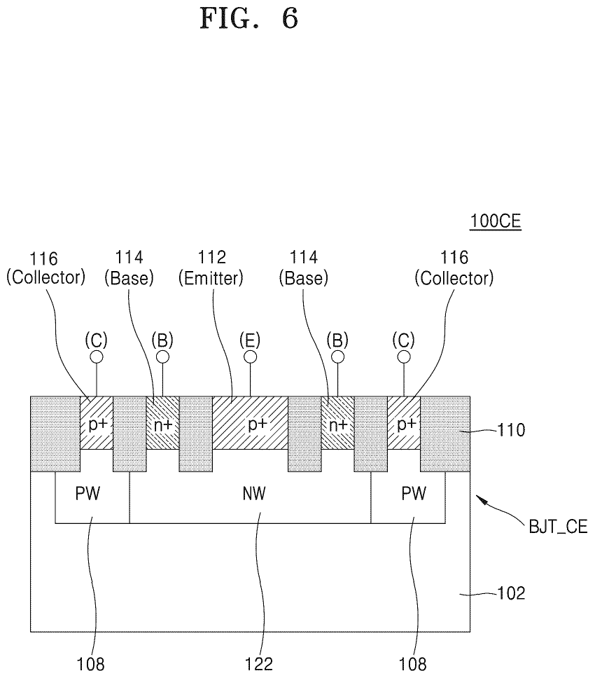

FIG. 6 is a cross-sectional view of an integrated circuit device 100CE including a bipolar junction transistor BJT_CE of a comparative example, to be compared with an integrated circuit device of the disclosure.

In detail, the integrated circuit device 100CE of the comparative example may include the bipolar junction transistor BJT_CE provided in the substrate 102. The bipolar junction transistor BJT_CE of the integrated circuit device 100CE of the comparative example may be the same as that of FIG. 1, except that an integrated well region 122 of the second conductivity type is arranged below the emitter 112 and the base 114.

The bipolar junction transistor BJT_CE of the integrated circuit device 100CE of the comparative example may be the same as that of FIG. 1, except that the emitter 112 and the base 114 are arranged on the integrated well region 122. The integrated well region 122 may be an integrated N-type well region NW.

The bipolar junction transistor BJT_CE may include the integrated well region 122 and the third well region 108 in the substrate 102. The third well region 108 may be the third P-type well region PW. The bipolar junction transistor BJT_CE may include the base 114 arranged on the integrated well region 122 and having the second conductivity type, and the base electrode B connected to the base 114.

The bipolar junction transistor BJT_CE may include the emitter 112 arranged on the integrated well region 122 and having the first conductivity type, and the emitter electrode E connected to the emitter 112. The bipolar junction transistor BJT_CE may include the collector 116 arranged on the third well region 108 and having the first conductivity type, and the collector electrode C connected to the collector 116. The bipolar junction transistor BJT_CE includes the device isolation regions 110 between the base 114 and the emitter 112 and between the base 114 and the collector 116.

In the bipolar junction transistor BJT_CE, a junction formation location between the emitter 112 and the base 114 may be presented on a poor interface generated by a device isolation formation process. Accordingly, the bipolar junction transistor BJT_CE may induce a recombination current according to an increase in an interface trap.

As a result, the bipolar junction transistor BJT_CE may have a poor characteristic of a transistor, e.g., a distribution of the voltage difference dVbe between the base 114 and the emitter 112 may not be uniform.

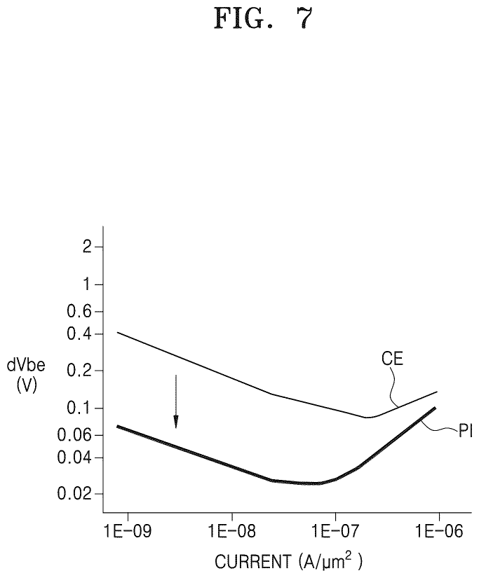

FIGS. 7 to 9 are diagrams showing a distribution of a voltage difference dVbe between a base and an emitter of a bipolar junction transistor of an integrated circuit device, according to embodiments.

In detail, in FIGS. 7 to 9, PI shows a distribution of the voltage difference dVbe between the base 114 and the emitter 112 of the bipolar junction transistor BJT of the integrated circuit device 100 of FIGS. 1 to 3. In FIGS. 7 to 9, CE shows a distribution of the voltage difference dVbe between the base 114 and the emitter 112 of the bipolar junction transistor BJT_CE of the integrated circuit device 100CE of the comparative example of FIG. 6.

FIG. 7 shows distributions of the voltage differences dVbe between the bases 114 and the emitters 112 according to application of a current per unit area (A/cm²) after setting temperatures of the bipolar junction transistor BJT of the integrated circuit device 100 of FIGS. 1 to 3 and the bipolar junction transistor BJT_CE of the integrated circuit device 100CE of FIG. 6 to 25° C. In FIG. 7, the Y-axis denotes a voltage (V). Referring to FIG. 7, it is determined that the distribution PI of the voltage difference dVbe of the disclosure is more uniform than the distribution CE of the voltage difference dVbe of the comparative example.

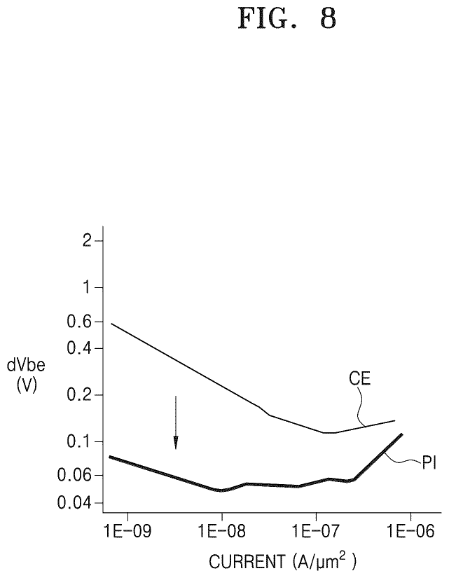

FIG. 8 shows distributions of the voltage differences dVbe between the bases 114 and the emitters 112 according to application of a current per unit area (A/cm²) after setting temperatures of the bipolar junction transistor BJT of the integrated circuit device 100 of FIGS. 1 to 3 and the bipolar junction transistor BJT_CE of the integrated circuit device 100CE of FIG. 6 to 40° C. In FIG. 8, the Y-axis denotes a voltage (V). Referring to FIG. 8, it is determined that the distribution PI of the voltage difference dVbe of the disclosure is more uniform than the distribution CE of the voltage difference dVbe of the comparative example.

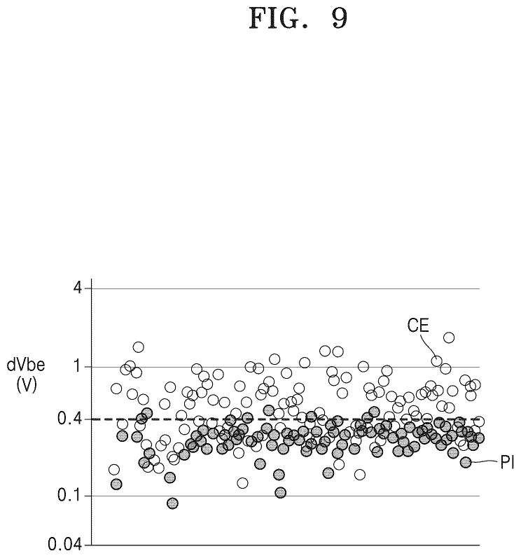

FIG. 9 shows distributions of the voltage differences dVbe between the bases 114 and the emitters 112 when a certain value, e.g., 1E-8, of a current per unit area (A/cm²) is input after setting temperatures of the bipolar junction transistor BJT of the integrated circuit device 100 of FIGS. 1 to 3 and the bipolar junction transistor BJT_CE of the integrated circuit device 100CE of FIG. 6 to 25° C. In FIG. 9, the Y-axis denotes a voltage (V). Referring to FIG. 9, it is determined that the distribution PI of the voltage difference dVbe of the disclosure is more uniform than the distribution CE of the voltage difference dVbe of the comparative example.

In the bipolar junction transistors BJT and BJT-1 of the integrated circuit devices 100, 100-1, and 300 of the disclosure described above, the first well region 106 having the second conductivity type is arranged in the substrate 102 below the base 114, and the first well region 106 has the first doping concentration. In the bipolar junction transistors BJT and BJT-1, the second well region 104 having the second conductivity type is arranged in the substrate 102 below the emitter 112, and the second well region 104 has the second doping concentration that is different from the first doping concentration. In the bipolar junction transistors BJT and BJT-1, the third well region 108 having the first conductivity type may be arranged in the substrate 102 below the collector 116. In the integrated circuit devices 100, 100-1, and 300 of the disclosure including such bipolar junction transistors BJT and BJT-1, a distribution of a voltage difference between the base 114 and the emitter 112, which are arranged on the substrate 102, may be uniform.

An integrated circuit device of the disclosure includes a bipolar junction transistor provided in a substrate. The bipolar junction transistor includes a first well region in the substrate below a base, wherein the first well region has a second conductivity type and a first doping concentration. The bipolar junction transistor includes a second well region in the substrate below an emitter, wherein the second well region has the second conductivity type and a second doping concentration that is different from the first doping concentration. The bipolar junction transistor includes a third well region in the substrate below a collector, wherein the third well region has a first conductivity type. An integrated circuit device of the disclosure including such a bipolar junction transistor may have a uniform distribution of a voltage difference between the base and the emitter, which are arranged on the substrate.

While the disclosure has been particularly shown and described with reference to embodiments thereof, it will be understood that various changes in form and details may be made therein without departing from the spirit and scope of the following claims.

What is claimed is:

1. An integrated circuit device comprising:
a substrate; and
a bipolar junction transistor in the substrate, wherein the bipolar junction transistor comprises:
a first well region of a second conductivity type in the substrate and having a first doping concentration;
a second well region adjacent to one side of the first well region in the substrate, of the second conductivity type, and having a second doping concentration that is different from the first doping concentration;
a third well region adjacent to another side of the first well region in the substrate and of a first conductivity type;
a base on the first well region and having the second conductivity type;
an emitter on the second well region and of the first conductivity type; and
a collector on the third well region and of the first conductivity type.

2. The integrated circuit device of claim 1, wherein the second doping concentration is greater than the first doping concentration.

3. The integrated circuit device of claim 1, wherein the base has a ring shape around the emitter and the collector has a ring shape around the base.

4. The integrated circuit device of claim 1, further comprising:
device isolation regions between the base and the emitter and between the base and the collector.

5. The integrated circuit device of claim 1, wherein a width of the second well region is greater than a width of the first well region.

6. The integrated circuit device of claim 1, further comprising:
a deep well region of the second conductivity type in the substrate,
wherein the first well region, the second well region, and the third well region are on the deep well region.

7. An integrated circuit device comprising:
a P-type substrate; and
a bipolar junction transistor in the P-type substrate, wherein the bipolar junction transistor comprises:
a first N-type well region in the P-type substrate and having a first doping concentration;
a second N-type well region adjacent to one side of the first N-type well region in the P-type substrate and having a second doping concentration that is different from the first doping concentration;
a third P-type well region adjacent to another side of the first N-type well region in the P-type substrate;
an N-type base on the first N-type well region;
a P-type emitter on the second N-type well region; and
a P-type collector on the third P-type well region.

8. The integrated circuit device of claim 7, wherein the second doping concentration is greater than the first doping concentration, and a width of the second N-type well region is greater than a width of the first N-type well region.

9. The integrated circuit device of claim 7, further comprising:
device isolation regions between the N-type base and the P-type emitter and between the N-type base and the P-type collector.

10. The integrated circuit device of claim 7, further comprising:
a deep N-type well region in the P-type substrate,
wherein the first N-type well region, the second N-type well region, and the third P-type well region are on the deep N-type well region.

11. An integrated circuit device comprising:
a substrate;
a metal-oxide semiconductor field effect transistor in the substrate (MOSFET), the MOSFET comprising a MOSFET well region of a first conductivity type; and
a bipolar junction transistor (BJT) in the substrate, the BJT comprising:
a first well region of a second conductivity type in the substrate and having a first doping concentration;
a second well region adjacent to one side of the first well region in the substrate, of the second conductivity type, and having a second doping concentration that is different from the first doping concentration;
a third well region adjacent to another side of the first well region in the substrate and of the first conductivity type;
a base on the first well region and having the second conductivity type;
an emitter on the second well region and of the first conductivity type; and
a collector on the third well region and of the first conductivity type.

12. The integrated circuit device of claim 11, wherein the second doping concentration is greater than the first doping concentration.

13. The integrated circuit device of claim 11, wherein the base has a ring shape around the emitter and the collector has a ring shape around the base.

14. The integrated circuit device of claim 11, further comprising:
device isolation regions between the base and the emitter and between the base and the collector.

15. The integrated circuit device of claim 11, wherein a width of the second well region is greater than a width of the first well region.

16. The integrated circuit device of claim 11, further comprising:
a deep well region of the second conductivity type in the substrate,
wherein the first well region, the second well region, and the third well region are on the deep well region.
